(19) United States
(12) Patent Application Publication
(10) Pub. No.: US 2008/0074205 A1
(43) Pub. Date: Mar. 27, 2008

(54) Reference Clock Out Feature on a Digital Device Peripheral Function Pin

(75) Inventors: Mei-Ling Chen, Chandler, AZ (US); Igor Wojewoda, Tempe, AZ (US); Gaurang Kavaiya, Chandler, AZ (US)

Correspondence Address: Baker Botts L.L.P.;Attention: Paul N. Katz, One Shell Plaza, 910 Louisiana Street, Houston, TX, 77002-4995, US

(73) Assignee: MICROCHIP TECHNOLOGY INCORPORATED

(21) Appl. No.: 11/776,636

(22) Filed: Jul. 12, 2007

Related U.S. Application Data
(60) Provisional application No. 60/827,075, filed on Sep. 27, 2006.

(51) Int. Cl. H03B 1/00

(52) U.S. Cl. 331/74

(57) ABSTRACT

An integrated circuit device comprising a configurable reference clock output to a peripheral function connection of the integrated circuit device provides a system clock or a frequency divided clock from the system clock as a clock source to a peripheral function on a peripheral function connection of the integrated circuit device. The clock function may be used to generate all necessary clocks for a plurality of integrated circuit devices and may be able to supply a system clock or frequency divided clock from the system clock, either from an external clock oscillator source or from an internally generated system clock, with the option of using a crystal for more accuracy and greater frequency stability. The external clock and/or internal clock may be made available for peripheral devices even when internal logic of the integrated circuit device may be in a standby/sleep mode.

### RELATED PATENT APPLICATION

This application claims priority to commonly owned U.S. Provisional Patent Application Ser. No. 60/827,075; filed Sep. 27, 2006; entitled “Reference Clock Out Feature on a Digital Device Peripheral Function Pin” by Mei-Ling Chen, Igor Wojewoda and Gaurang Kavaiya; and is hereby incorporated by reference herein for all purposes.

### TECHNICAL FIELD

The present disclosure relates to semiconductor integrated circuit devices having multipurpose input-output pads, and more specifically, to semiconductor integrated circuit devices having multipurpose input-output pads with interface compatibilities for a system clock, either externally and/or internally generated, and provisions for an external crystal to control the frequency of an internal clock oscillator. A configurable reference clock output to a peripheral function pin allows delivery of a clock or frequency divided clock from an internal oscillator or an external system clock to a peripheral function pin(s) of the integrated circuit device. This provides an additional reference clock output that may be adapted to supply a clock or a frequency divided system clock to internal and/or external device logic circuits independently of whether the integrated circuit device logic is operationally active or in a standby/sleep mode.

### BACKGROUND

Logic circuits in integrated circuit devices, e.g., microprocessor, microcontroller, digital signal processor (DSP), programmable logic array (PLA), application specific integrated circuit (ASIC), etc., require clock signals for sequentially processing program instructions and data. These clock signals may be generated within an integrated circuit device or by external circuits thereto. Many applications require precise clock frequencies that may be determined with a stable clock source, e.g., using a highly frequency stable crystal oscillator. The crystal may be external to the integrated circuit device and may be coupled to an internal oscillator circuit that may be adapted to produce a clock output(s) based upon the frequency of oscillation determined by the external crystal. An integrated circuit device may also be adapted to receive an externally generated clock signal for operation of its internal logic circuits. However when more than one integrated circuit device of an electronic system requires a clock signal, each device requires its own clock or a clock driver having enough output drive capabilities for connecting to more than one integrated circuit device.

### SUMMARY

Therefore, there is a need for the ability of connecting a configurable reference clock output to a peripheral function connection of an integrated circuit device so that a system clock or a frequency divided clock from the system clock may be available as a clock source at the peripheral function connection, e.g., pin of the integrated circuit device. This clock signal at the peripheral function connection may be used by an external peripheral device whether the integrated circuit device logic is operational or in a standby/sleep mode. According to the teachings of this disclosure, a clock function may be used to generate all of the necessary clocks for a plurality of integrated circuit devices, instead of having to use multiple oscillators for generating clock signals for each of the plurality of integrated circuit devices.

Thus, the additional clock output connection of the integrated circuit device may be able to supply a system clock or frequency divided clock from the system clock, either from an external clock oscillator source or from an internally generated system clock whose frequency is accurately and stably determined, e.g., by a crystal. When the internal oscillator and external crystal are configured as a stable clock source, a clock output from this crystal oscillator may be made available on the peripheral function connection of the integrated circuit device. This results in simpler and more cost effective clock solutions for electronic systems using a plurality of integrated circuit devices.

In addition, the integrated circuit device may have some kind of sleep or standby mode. Generally, in the sleep or standby mode, clock generation is turned off. However according to teachings of this disclosure, internal logic of a main device may go into a standby/sleep mode without turning off the main device's clock generation circuit so that other peripheral devices requiring a clock signal may continue to operate while the main device remains in the standby/sleep mode.

According to a specific example embodiment of this disclosure, an integrated circuit device may comprise: a first external clock/crystal connection; an internal clock oscillator; logic circuits; a clock source selection switch having a first input coupled to the first external clock/crystal connection, a second input coupled to the internal clock oscillator, and an output, wherein the output of the clock source selection switch is coupled to either the first or the second input thereof; an oscillator/buffer circuit having an input coupled to the output of the clock source selection switch and adapted for producing a clock signal, wherein the clock signal is coupled to the logic circuits; and an external peripheral clock connection coupled to the output of the oscillator/buffer circuit, wherein the external peripheral clock connection is available for supplying a clock to at least one peripheral device.

According to another specific example embodiment of this disclosure, an integrated circuit device may comprise: a first external clock/crystal connection; logic circuits; a oscillator/buffer circuit having an input coupled to the first external clock/crystal connection and adapted for producing a clock signal, wherein the clock signal is coupled to the logic circuits; and an external peripheral clock connection coupled to the first external clock/crystal connection, wherein the external peripheral clock connection is available for supplying a clock to at least one peripheral device.

### BRIEF DESCRIPTION OF THE DRAWINGS

A more complete understanding of the present disclosure thereof may be acquired by referring to the following description taken in conjunction with the accompanying drawings wherein:

FIG. 1 is a schematic block diagram of a portion of an integrated circuit device configurable to have an external clock source, crystal controlled oscillator or internal clock oscillator for supplying system clocks for both device logic and external logic, according to a specific example embodiment of this disclosure;

FIG. 2 is a schematic block diagram of a portion of an integrated circuit device configurable to have an external clock source, crystal controlled oscillator and/or internal clock oscillator for supplying system clocks for both device logic and external logic, according to another specific example embodiment of this disclosure; and

FIG. 3 is a schematic block diagram of a portion of an integrated circuit device configurable to have an external clock source or crystal controlled oscillator for supplying system clocks for both device logic and external logic, according to yet another specific example embodiment of this disclosure.

While the present disclosure is susceptible to various modifications and alternative forms, specific example embodiments thereof have been shown in the drawings and are herein described in detail. It should be understood, however, that the description herein of specific example embodiments is not intended to limit the disclosure to the particular forms disclosed herein, but on the contrary, this disclosure is to cover all modifications and equivalents as defined by the appended claims.

### DETAILED DESCRIPTION

Referring now to the drawings, the details of specific example embodiments are schematically illustrated. Like elements in the drawings will be represented by like numbers, and similar elements will be represented by like numbers with a different lower case letter suffix.

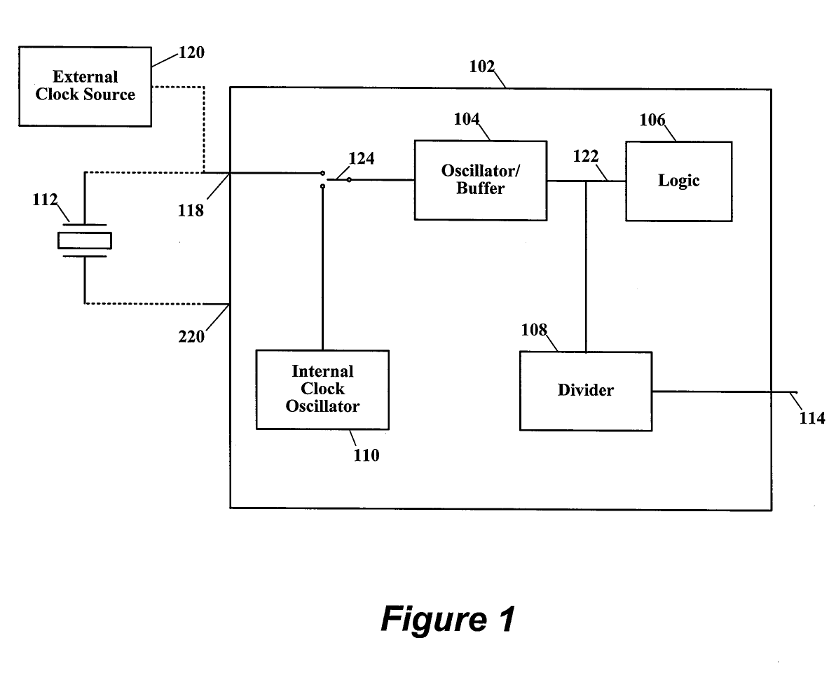

Referring to FIG. 1, depicted is a schematic block diagram of a portion of an integrated circuit device configurable to have an external clock source, crystal controlled oscillator or internal clock oscillator for supplying system clocks for both device logic and external logic, according to a specific example embodiment of this disclosure. An integrated circuit device 102, e.g., microprocessor, microcontroller, digital signal processor (DSP), programmable logic array (PLA), application specific integrated circuit (ASIC), etc., may be adapted to use an external clock source 120, an external crystal 112 in combination with a oscillator/buffer 104, or an internal clock oscillator 110.

A peripheral clock output 114 may be available and configurable for a desired clock frequency for other integrated circuit digital devices (not shown). This feature saves cost and printed circuit board space by eliminating the need for additional clock sources and/or clock drivers for the other integrated circuit digital devices of the electronic system (not shown).

The digital device 102 may comprise an oscillator/buffer 104, a frequency divider 108, an internal clock oscillator 110, a clock source selection switch 124, and logic circuits 106. The oscillator/buffer 104 may be coupled to an external crystal 112 or an external clock source 120 at input 118, or to an internal clock oscillator 126 with the clock source selection switch 124. The oscillator/buffer 104 may, acting as a crystal oscillator, generate a clock signal at a frequency determined by the external crystal 112, or as a clock buffer when coupled to either the external clock source 120 or the internal clock oscillator 126 through the clock source selection switch 124.

Switching between the external clock source 120, the external crystal 112, or the internal clock oscillator 110 may be done synchronously so as not to produce any undesired “glitches” that could be mistaken for a clock signal. A output 122 from the oscillator/buffer 104 may be coupled to a clock divider 108, e.g., divide by a positive integer value. The output of the clock divider 108 may be coupled to a peripheral clock output 114 and is available for use as another clock signal to the other integrated circuit devices (not shown). The divide ratio of the clock divider 108 may be programmable. The clock divider 108 may also be used as a pass through circuit that does not change the frequency of the clock the output 122. It is contemplated and with the scope of this disclosure that the logic 106 may go into a standby/sleep mode without affecting operation of the clock generation circuits described hereinabove so that a clock signal may be present at the output 114 for use by the other integrated circuit devices (not shown).

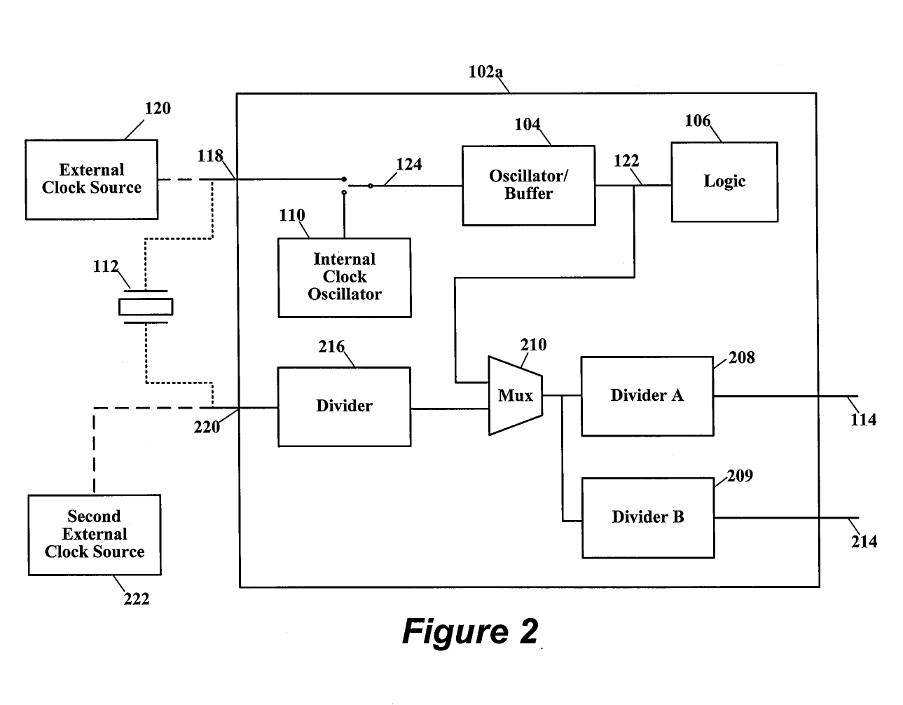

Referring to FIG. 2, depicted is a schematic block diagram of a portion of an integrated circuit device configurable to have an external clock source, crystal controlled oscillator and/or internal clock oscillator for supplying system clocks for both device logic and external logic, according to another specific example embodiment of this disclosure. An integrated circuit device 102a, e.g., microprocessor, microcontroller, digital signal processor (DSP), programmable logic array (PLA), application specific integrated circuit (ASIC), etc., may be adapted to use an external clock source 120, an external crystal 112 in combination with a oscillator/buffer 104, or an internal clock oscillator 110. In addition another external clock source 222 may be coupled to a clock input 220, and may be used to supply frequency divided clocks at peripheral clock outputs 114 and 214 for other devices, e.g., peripherals, on the system board (not shown) that may operate at different clock speeds. This may be used to reduce system costs by eliminating two additional oscillator components, e.g., external crystals.

The digital device 102a may comprise a oscillator/buffer 104, a first frequency divider 208, an internal clock oscillator 110, a clock source selection switch 124, a second frequency divider 216, a third frequency divider 209, a clock source multiplexer 210, and logic circuits 106. The oscillator/buffer 104 may be coupled to an external crystal 112, an external clock source 120 or an internal clock oscillator 126 with the clock source selection switch 124. The oscillator/buffer 104 may, acting as a crystal oscillator, generate a clock signal at a frequency determined by the external crystal 112, or as a clock buffer when coupled to either the external clock source 120 or the internal clock oscillator 126 through the clock source selection switch 124.

The oscillator/buffer 104 may provide a clock signal 122 that may be coupled to the logic 106 and an input of the clock multiplexer 210. Another input of the clock multiplexer 210 may be coupled to an output of the second frequency divider 216. The clock multiplexer 210 may thereby be used to select a clock source to be divided by the first frequency divider 208, and to provide this frequency divided clock source at the peripheral clock output 114 for use as another clock signal to the other integrated circuit devices (not shown). The third frequency divider 209 maybe used to provide another frequency divided clock source at the peripheral clock output 214 and may be used as an additional clock signal to yet other integrated circuit devices (not shown). It is contemplated and within the scope of this disclosure that a plurality of frequency dividers may be implemented into the digital device 102a, wherein the outputs from each of the plurality of frequency dividers may be used to provide clock signals at the same or different frequencies and for supporting a variety of peripherals devices (not shown), e.g., Ethernet interface, wireless bridge, USB, etc. Thus, cost and space savings of a reduction of oscillator components, e.g., external crystals may be achieved.

The first frequency divider 208 and/or third frequency divider 209 may also be used as a pass through circuit(s) that does not change the frequency of the clock at the output 122. Similarly, the second frequency divider 216 may also be used as a pass through circuit that does not divide the clock frequency received at the input 220.

Switching between the external clock source 120 or crystal 112 and the internal clock oscillator 110 may be done synchronously so as not to produce any undesired “glitches” that could be mistaken for a clock signal. Likewise, switching between the clock signal 122 and the output of the second frequency divider 216 may be done synchronously so as not to produce any undesired “glitches” that could be mistaken for a clock signal.

The frequency divide ratio of the first frequency divider 208, third frequency divider 209, and/or second frequency divider 216 may be programmable and divide frequencies by any positive integer value. The output of the first frequency divider 208 may be coupled to the peripheral clock output 114 and is available for use as a lower frequency clock signal to the other integrated circuit devices (not shown). The output of the third frequency divider 209 may be coupled to the peripheral clock output 214 and is available for use as a lower frequency clock signal to still other integrated circuit devices (not shown) that may require a different clock frequency that the clock available at the peripheral clock output 114.

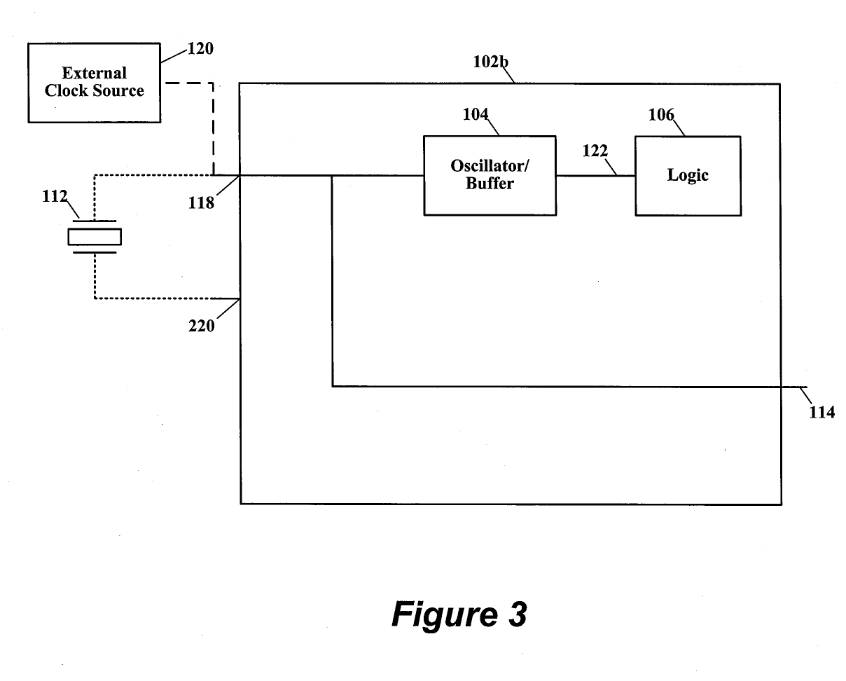

Referring to FIG. 3, depicted is a schematic block diagram of a portion of an integrated circuit device configurable to have an external clock source or crystal controlled oscillator for supplying system clocks for both device logic and external logic, according to yet another specific example embodiment of this disclosure. An integrated circuit device 102b, e.g., microprocessor, microcontroller, digital signal processor (DSP), programmable logic array (PLA), application specific integrated circuit (ASIC), etc., may be adapted to use an external clock source 120 or an external crystal 112 in combination with a oscillator/buffer 104.

A peripheral clock output 114 may be available and configurable for a desired clock frequency for other integrated circuit digital devices (not shown). This feature saves cost and printed circuit board space by eliminating the need for additional clock sources and/or clock drivers for the other integrated circuit digital devices of the electronic system (not shown).

The digital device 102 may comprise an oscillator/buffer 104, and logic circuits 106. The oscillator/buffer 104 may be coupled to an external crystal 112 or an external clock source 120 at input 118. The oscillator/buffer 104 may, acting as a crystal oscillator, generate a clock signal at a frequency determined by the external crystal 112, or as a clock buffer when coupled to the external clock source 120.

Switching between the external clock source 120 or the external crystal 112 may be done synchronously so as not to produce any undesired “glitches” that could be mistaken for a clock signal. It is contemplated and with the scope of this disclosure that the logic 106 may go into a standby/sleep mode without affecting operation of the clock generation circuits described hereinabove so that a clock signal may be present at the output 114 for use by the other integrated circuit devices (not shown).

While embodiments of this disclosure have been depicted, described, and are defined by reference to example embodiments of the disclosure, such references do not imply a limitation on the disclosure, and no such limitation is to be inferred. The subject matter disclosed is capable of considerable modification, alteration, and equivalents in form and function, as will occur to those ordinarily skilled in the pertinent art and having the benefit of this disclosure. The depicted and described embodiments of this disclosure are examples only, and are not exhaustive of the scope of the disclosure.

What is claimed is:

1. An integrated circuit device, comprising:
a first external clock/crystal connection;
an internal clock oscillator;
logic circuits;
a clock source selection switch having a first input coupled to the first external clock/crystal connection, a second input coupled to the internal clock oscillator, and an output, wherein the output of the clock source selection switch is coupled to either the first or the second input thereof;
an oscillator/buffer circuit having an input coupled to the output of the clock source selection switch and adapted for producing a clock signal, wherein the clock signal is coupled to the logic circuits; and
an external peripheral clock connection coupled to the output of the oscillator/buffer circuit, wherein the external peripheral clock connection is available for supplying a clock to at least one peripheral device.

2. The integrated circuit device of claim 1, further comprising a first frequency divider coupled between the oscillator/buffer circuit output and the external peripheral clock connection, wherein the external peripheral clock connection is available for supplying a frequency divided clock to the at least one peripheral device.

3. The integrated circuit device of claim 1, further comprising a crystal coupled to the first external clock/crystal connection, whereby the crystal determines a frequency of the clock signal.

4. The integrated circuit device of claim 1, wherein an external clock source is coupled to the first external clock/crystal connection and determines a frequency of the clock signal.

5. The integrated circuit device of claim 1, further comprising:
a second external clock connection;
a clock multiplexer having a first input coupled to the clock signal from the output of the oscillator/buffer circuit, a second input coupled to the second external clock connection and an output coupled to the external peripheral clock connection.

6. The integrated circuit device of claim 4, further comprising a second frequency divider coupled between the clock multiplexer output and the external peripheral clock connection, wherein the external peripheral clock connection is available for supplying a frequency divided clock to the at least one peripheral device.

7. The integrated circuit device of claim 2, wherein the first frequency divider is programmable.

8. The integrated circuit device of claim 7, wherein the first frequency divider divides the clock signal frequency by N, where N is a positive integer value.

9. The integrated circuit device of claim 6, wherein the second frequency divider is programmable.

10. The integrated circuit device of claim 9, wherein the second frequency divider divides a signal frequency from the output of the clock multiplexer by N, where N is a positive integer value.

11. The integrated circuit device of claim 1, wherein the integrated circuit device is selected from the group consisting of a microprocessor, a microcontroller, a digital signal processor (DSP), a programmable logic array (PLA), and an application specific integrated circuit (ASIC).

12. The integrated circuit device of claim 1, wherein the clock source selection switch synchronously transfers between the first external clock/crystal connection and the internal clock oscillator.

13. The integrated circuit device of claim 5, wherein the clock multiplexer synchronously transfers between the output of the oscillator/buffer circuit and the second external clock connection.

14. The integrated circuit device of claim 6, wherein the clock multiplexer synchronously transfers between the output of the oscillator/buffer circuit and the output of the second frequency divider.

15. The integrated circuit device of claim 1, wherein the logic circuits have a standby/sleep mode independent of the oscillator/buffer circuit.

16. An integrated circuit device, comprising:
a first external clock/crystal connection;
logic circuits;
a oscillator/buffer circuit having an input coupled to the first external clock/crystal connection and adapted for producing a clock signal, wherein the clock signal is coupled to the logic circuits; and
an external peripheral clock connection coupled to the first external clock/crystal connection, wherein the external peripheral clock connection is available for supplying a clock to at least one peripheral device.

17. The integrated circuit device of claim 16, further comprising a first frequency divider coupled between the oscillator/buffer circuit output and the external peripheral clock connection, wherein the external peripheral clock connection is available for supplying a frequency divided clock to the at least one peripheral device.

18. The integrated circuit device of claim 16, further comprising a crystal coupled to the first external clock/crystal connection, whereby the crystal determines a frequency of the clock signal.

19. The integrated circuit device of claim 16, wherein an external clock source is coupled to the first external clock/crystal connection and determines a frequency of the clock signal.

20. The integrated circuit device of claim 16, further comprising:
a second external clock connection;
a clock multiplexer having a first input coupled to the clock signal from the output of the oscillator/buffer circuit, a second input coupled to the second external clock connection and an output coupled to the external peripheral clock connection.

21. The integrated circuit device of claim 20, further comprising a second frequency divider coupled between the clock multiplexer output and the external peripheral clock connection, wherein the external peripheral clock connection is available for supplying a frequency divided clock to the at least one peripheral device.

22. The integrated circuit device of claim 17, wherein the first frequency divider is programmable.

23. The integrated circuit device of claim 22, wherein the first frequency divider divides the clock signal frequency by N, where N is a positive integer value.

24. The integrated circuit device of claim 21, wherein the second frequency divider is programmable.

25. The integrated circuit device of claim 24, wherein the second frequency divider divides a signal frequency from the output of the clock multiplexer by N, where N is a positive integer value.

26. The integrated circuit device of claim 16, wherein the integrated circuit device is selected from the group consisting of a microprocessor, a microcontroller, a digital signal processor (DSP), a programmable logic array (PLA), and an application specific integrated circuit (ASIC).

27. The integrated circuit device of claim 20, wherein the clock multiplexer synchronously transfers between the output of the oscillator/buffer circuit and the second external clock connection.

28. The integrated circuit device of claim 21, wherein the clock multiplexer synchronously transfers between the output of the oscillator/buffer circuit and the output of the second frequency divider.

29. The integrated circuit device of claim 16, wherein the logic circuits have a standby/sleep mode independent of the oscillator/buffer circuit.

30. The integrated circuit device of claim 4, further comprising a plurality of frequency dividers coupled between the clock multiplexer output and a plurality of external peripheral clock connections, wherein each of the plurality of external peripheral clock connections is available for supplying a frequency divided clock to respective ones of a plurality of peripheral devices.

31. The integrated circuit device of claim 30, wherein one or more of the plurality of frequency dividers may be set to different divide frequencies for compatibility with the respective ones of the plurality of peripheral devices. _
